(19) United States
(12) Patent Application Publication
(10) Pub. No.: US 2022/0327457 A1
(43) Pub. Date: Oct. 13, 2022

(54) SYSTEM FOR PLANNING, MAINTAINING, MANAGING AND OPTIMIZING A PRODUCTION PROCESS

(71) Applicant: BAYER AKTIENGESELLSCHAFT, Leverkusen (DE)

(72) Inventors: Rubin HILLE, Köln (DE); Vera COLDITZ, Frankfurt (DE); Ingo KNABBEN, Leverkusen (DE); Maike TEMMING, Leverkusen (DE); Tamara SPIES, Billigheim (DE)

(21) Appl. No.: 17/640,288

(22) PCT Filed: Aug. 31, 2020
(86) PCT No.: PCT/EP2020/074208

§ 371 Date: Mar. 3, 2022

(30) Foreign Application Priority Data
Sep. 6, 2019 (EP) 19195965.9

(51) Int. Cl. G06Q 10/06; G06Q 10/04

(52) U.S. Cl. CPC G06Q 10/06395; G06Q 10/0631; G06Q 10/04

(57) ABSTRACT

The present invention relates in general to the field of model-based planning, maintaining, managing and optimizing a production process in a production plant comprising a plurality of plant components with limited periods of use, wherein the production process consists of a plurality of partial processes, and comprises at least one replacement or cleaning step of the plant component with a limited period of use. The solution according to the invention is in particular intended for the optimization of the production of a chemical compound and/or a formulation thereof as the result of a production process that comprises more than one partial process. It relates further to a solution for cause analysis for the identification of parameters affecting the manufacture.

The present invention relates generally to the field of model-based planning, maintaining, managing and optimizing a production facility. The solution according to the invention is in particular intended for the optimization of the production of a chemical compound and/or a formulation thereof as the result of a production process that comprises more than one partial process. It relates further to a solution for cause analysis for the identification of parameters affecting the manufacture.

Chemical compound or product refers, in the context of this application, to any compound that is manufactured through an organic or biochemical method process. The molecule can be small or large, such as polymers, polysaccharides, polypeptides, antibodies, therapeutic proteins . . . A production process of this type typically comprises not only the steps that lead to the product itself, but also cleaning and formulation steps as well as plant components and plant construction, cleaning of the production plant, disposal processes, the supply of energy and medium, feed paths and/or recycling steps. Each element of the plant or step of the production process and/or their parameters can contribute to optimization of the production process.

The demand for biopharmaceutical products has risen continuously over recent decades. Time-to-market, cost efficiency and flexibility in manufacture are nowadays central topics in the development of biopharmaceutical processes. Continuous bioproduction and single-use technologies promise an approach to a solution in order to overcome these obstacles, since high space-time yields can be achieved, and smaller installations, which are therefore flexible, are used.

Economical processes must be established at the same time, if biosimilars come onto the market. Many biological process strategies that satisfy these requirements are proposed. The manufacturers must select suitable options that correspond to the current production possibilities and to the molecule pipeline. A systematic process development that shortens the time-to-market is moreover of great importance, in particular for high-value biopharmaceuticals. To realize this, it is necessary to know the profitability of the manufacture even in the early development phase.

Continuous upstream process strategies for the cell culture of mammalian cells as part of the continuous manufacture of biopharmaceuticals in particular offer potential for these challenges. They are more productive, and therefore produce the same quantity in smaller plants. The first continuous cell cultures were realized toward the end of the 1980s. The limited scaling potential, and the liability to errors in continuous culture systems of the first generation, led in the past to an emphasis on well-understood batch and fed-batch culture strategies. Newer types of cell retention systems that enable continuous fermentation, and the introduction of single-use technologies, met renewed interest, since they overcome these obstacles.

Careful and reliable planning and optimization of production processes is crucial in an environment driven by competition. The cost structures of production processes are analyzed using cost models. Commercial models cannot be applied to biopharmaceutical processes [S. S. Farid, “Process economics of industrial monoclonal antibody manufacture,” Journal of Chromatography B, vol. 848, no. 1, pp. 8-18, 2007]. There are, however, only a few reliable instruments, above all though for evaluating the economic performance of batch bioprocesses [P. Bunnak, R. Allmendinger, S. V. Ramasamy, P. Lettieri and N. J. Titchener-Hooker, “Life-cycle and cost of goods assessment of fed-batch and perfusion-based manufacturing processes for mAbs,” Biotechnology Progress, vol. 32, no. 5, pp. 1324-1335, 2016; D. Petrides, “Batch Process Simulation,” in Batch Processing: Modeling and Design, Urmila Diwekar, 2014, D. Pollard, M. Brower, Y. Abe, A. G. Lopes and A. Sinclair, “Standardized Economic Cost Modeling for Next-Generation MAb Production,” 2016. [Online]. Available: https://bioprocessintl.com/business/economics/standardized-economic-cost-modeling-next-generation-mab-production/. [Accessed 13 Feb. 2019]. The applicability of these tools to continuous processes is limited, since they cannot represent the dynamic behavior of these processes.

The object of providing a model-based solution that supports the development and design of a more economical and more robust manufacturing process, and which can be applied to both fed-batch and continuous processes, therefore arose. The solution should enable the prediction of a quality attribute that is significant for the manufacturing process. The solution according to the invention should, in particular, be capable of identifying the production parameters with the greatest influence on the manufacture in terms of the product and of the production plant and its operation for a production project as a predictive instance, and of providing optimization proposals for these influencing parameters in terms of one or more quality attributes for the production process.

The solution according to the invention should enable studies of parameters and sensitivities to be carried out for various operating modes, in order to indicate the variations to changes of the most important process parameters.

The solution according to the invention should, moreover, provide proposals for achieving production whose quality attributes have been optimized. In one particular embodiment, the information generated by the method should offer a deeper insight into the profitability of different manufacturing scenarios.

The solution according to the invention should in particular enable the comparison of fed-batch and continuous production processes, in particular of biotechnological processes, but also be applicable for other problems.

The object is achieved by a method or system as claimed in one of claims 1 to 15.

In the solution according to the invention, the production model and quality functions are combined, wherein the production model represents at least one replacement or cleaning step of plant components with limited period of use, and the period of use of the respective plant component is defined as one of the parameters influencing the production process (also known as process settings).

The production model represents mathematical relationships between the process settings as input variables and simulation variables, including, inter alia, quality attributes of the product.

The attribute functions specify the mathematical relationship between the process settings or the simulation variable on the one hand, and a quality attribute for the production process as an output variable of the method according to the invention.

Using the solution according to the invention, a sensitivity analysis of the parameters of the production process that have an influence can be carried out in the production model.

The invention is described in more detail below without distinguishing between the aspects of the invention (method and system). The explanations that follow shall instead apply analogously to all aspects of the invention, regardless of the context (method or system) in which they are given.

Production processes in the sense of the application are, in particular, processes for the manufacture of a chemical compound or of a chemical product.

Chemical compound or product refers to any compound that has been manufactured by an organic or biochemical method. The molecule can be small or large, such as polymers, polysaccharides, polypeptides or antibodies.

Typical partial processes that are suspected of having an influence on the quality attributes of the production process are chemical/biochemical reactions in a (bio)reactor, cleaning steps, the replacement of consumable materials, cleaning steps with or without interruption of the process, preliminary cultures, cell separations, cell recycling, chromatography, distillation and so forth, recycling steps, further process interruptions, the formulation of solid materials such as granulation, tableting and coating, analytical steps and disposal steps. Procurement steps can also be taken into consideration in the solution according to the invention.

Referred to as consumable materials are in particular single use systems (https ://dechema.de/dechema_media/Downloads/Positionspapiere/StatPap_SingleUse_2011_englisch-called_by-dechema-original_page-124930-original_site-dechema_eV-p-4298-view_image-1.pdf) or more generally plant components that have to be replaced or cleaned in the course of production, such as for example membranes, filters, sensors, pumps, bags and so forth.

Numerous combinations of partial processes will be envisaged by the person skilled in the art.

Partial processes and their parameters can influence both the simulation variables (also referred to as the simulation result) as well as the quality attribute for the production process.

The bottom-up principle of the in-silico method provides detailed insight into the most important parameters affecting manufacture.

Typical quality attributes for a production process (also known as the production quality attribute) include, by way of example and without being restricted to, the following:
CO2 emissions footprint,
costs,
energy consumption,
total process yield,
optimum charge throughput times,
consumption of consumable materials and medium,
flexibility.

Process settings refer in the context of the application to the characteristic parameters or properties of the production process, the partial processes and the corresponding plant components, as well as the consumable materials. Process settings can be fixed or variable over time.

Typical process settings include, without being limited to, the following:
partial processes and their duration, as well as operating means, i.e. technical equipment, machines and apparatus for operating production processes (also known as plant components),
the properties of the plant components, in particular their period of use, consumption, operating parameter limits, procurement expense and stocking,
cell lines, medium composition
scale, processing method—batch or continuous, throughput time, perfusion rate in the steady-state as values or as curve, target or maximum cell density.

Special process settings represent process parameters. These can be primary (measured parameters) and/or secondary parameters (indirect parameters, e.g., kinetic information). Examples of such process parameters are:
quality features of starting material(s) and/or intermediate product(s) that are generated in a partial process,
concentrations of starting material(s) and/or intermediate product(s), concentrations of byproduct(s),
physical parameters of the process or of the partial process—for example temperature, pH, dissolved oxygen (DO), agitator speed and so forth . . .
control parameters such as level and/or flow control schemes, cascades, feedforward and/or restriction control schemes,
individual values or temporal deviations as well as tolerances for parameter deviations, . . .

Examples of process parameters for cleaning steps are: period of use, cleaning duration, quantity and type of cleaning agents employed, disposal of the (contaminated) materials.

Examples of process parameters for replacement steps are: period of use, replacement duration, duration of process interruption, quantity and type of the operating materials, disposal of the (contaminated) materials and/or operating materials. The procurement of the operating materials can also be taken into consideration as a process parameter as can, for example, working time.

Examples of process parameters for recycling steps are: concentration of the returned materials, throughput rate (continuous) or quantity (batch), return system.

Examples of secondary parameters are: heat flow rate calculated from the heat balance (using volumes, throughput rates and temperatures), stoichiometry of the starting materials, quality attributes from earlier batches or earlier time intervals for continuous production projects. The last points allow delayed effects of, for example, circulation flows, residual materials in filter(s) and container(s), reactors, columns and so forth to be taken into consideration.

Secondary parameters are also preferably taken into consideration by the production model; values for these secondary parameters are calculated as required for the production model from the primary parameters, and provided to the production model for calculating the simulation results.

Further process settings include, for example:
current consumption and/or other energy consumption, water consumption, floor area,
working time and qualifications such as, for example, for the operation, procurement effort, disposal effort and so forth.

A distinction is typically made between fixed and variable process settings.

Values, value ranges or also time-series data, can be provided for the process settings. Values for the process settings are typically provided in the form of a table.

Preferably, working times and qualifications, floor areas, current consumption and water consumption are specified as fixed process settings for the respective partial processes.

In terms of the method, some of the process settings can be improved through simulations and optimization steps. Examples of optimizable process settings are, in particular, period of use of the plant components, throughput time, perfusion rate, cell density, and the majority of physical parameters.

With the solution according to the invention, however, scenarios can also be compared, and the optimum choice can be made. Process settings that can be optimized by means of a comparison are the selection of the cell line, the medium composition and the process method, but are not limited to these.

As a rule, process settings that change over time can be optimized by simulation and by optimization steps. Fixed process settings can be achieved through the simulation of scenarios and comparison of the values of the production quality attribute or attributes.

Simulation results (also known as process simulation results) refer, in the context of the application, and without being restricted to these, in particular to:
state of the plant modules and/or of their plant components such as, for example, product permeability of a membrane, without being limited to this. Through the use of “intelligent” plant modules, their state can be ascertained better,
space-time yield,
concentration of main products and/or byproducts in the form of time-series of the individual components (cell density, antibody etc.) over the processing period,
product quality attributes such as, for example, stability, homogeneity, purity, specificity, viscosity, drying losses, crystallization, particle size distribution, tablet hardness, active ingredient (API) or the general release of active material or the release rate of active materials in a formulation etc.
process flows in particular of medium, gas and/or feed.

For a biotechnological method, typical simulation results are:
total process yield,
concentration of main products and/or byproducts in a reactor or in a formulation, including in the form of time-series of the individual components (cell density, antibody etc.) over the processing period,
product quality attributes such as, for example, stability, homogeneity, purity, specificity.

The simulation results can be calculated as values or as curves against time.

Some features of the production process can be prespecified or optimized. Such features are, for example, process throughput time and the number of replacements and/or cleaning operations of plant modules, without being limited to them.

In one special embodiment of the solution according to the invention, the multiple simulation results are optimized against one another.

For calculating the attribute functions, parameter values are typically provided in the form of a table. Parameters of the attribute function are typically attribute values per unit (in particular chemicals, gases, plant modules), per m² (for areas) or per hour (working time), depending on which variable the attribute function should describe. If costs are calculated as a production quality attribute, parameters of the attribute functions are costs per hour, costs per unit, costs per m² and so on. If the CO2 emission footprint of the production process is ascertained, parameters of the attribute function are the CO2 footprint of the respective components of the production process.

The selection, or a combination, of the simulation results emerges from an analysis of the production process of the corresponding plant and of the process settings. Starting from the necessary simulation results, the corresponding process models are provided.

To carry out the method according to the invention, at least one process model is required that specifies or represents the mathematical relationships between a simulation result as an output and the process settings as an input.

In the case of the biotechnological production process, the method uses process models that precisely describe the dynamic relationship between the product and the metabolites in the production plant. The variation of a simulation result can be determined dynamically with the aid of the process model; the variations of the production quality attribute can accordingly also be determined dynamically.

This dynamic determination enables, for example, the optimization of the operating mode for the production process through the use of optimization steps.

According to the invention, the method uses one or a plurality of process models or partial process models and attribute functions, wherein:
a (partial) process model specifies or represents mathematical relationships between a simulation result and process settings,
an attribute function specifies or represents a mathematical relationship between the process settings and/or simulation results on the one hand, and the quality attribute of the production process on the other hand. Parameters of the attribute functions are moreover required for the calculation of the attribute function.

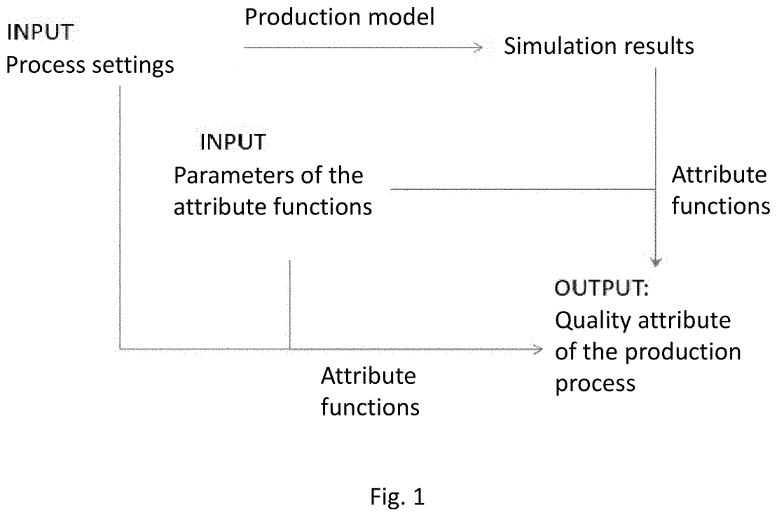

The method according to the invention is illustrated schematically in FIG. 1.

Through the calculation of the attribute functions, the corresponding value for the quality attribute of the production process is calculated.

Through a systematic variation of the values of the process settings within a range that is acceptable for the simulation result, the values for the process settings and the corresponding value for the quality attribute of the production process can be optimized.

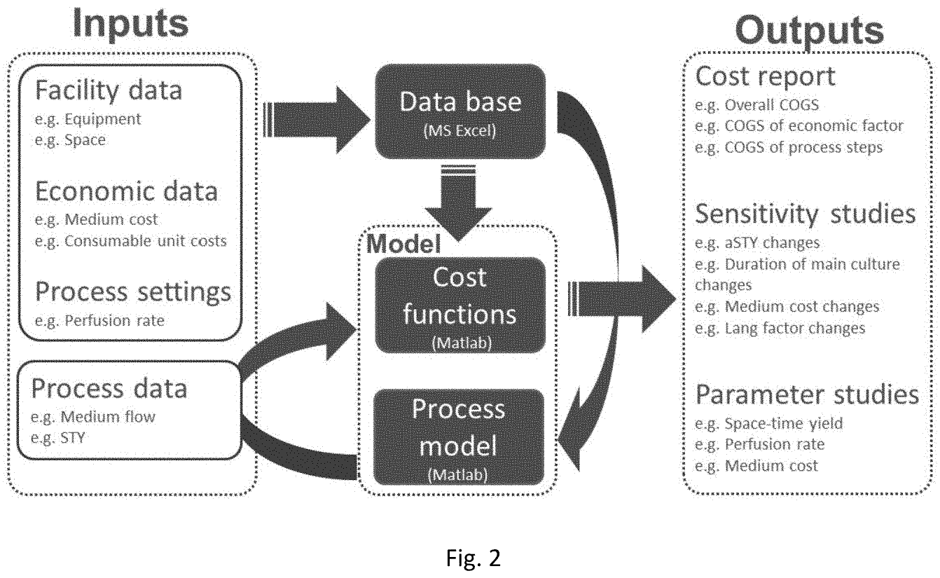

In FIG. 2 an overview of the method of the invention for a cost calculation is illustrated with the inputs and outputs.

The production model is typically a hybrid model that can comprise a plurality of empirical and/or mechanistic process models or partial process models.

The production model in particular comprises one or a plurality of mechanistic models for one or a plurality of steps, for example thermodynamic and/or kinetic models. Such mechanistic models are typically fundamental models that use fundamental chemical and/or physical principles such as the heat and mass balance, diffusion, flow mechanics, chemical reactions and so forth. A mechanistic model typically consists of differential equations for the description of fundamental principles (mechanisms) that are calibrated with reference to historic process time-series data (input data). Historic process time-series data are time-series of process parameter values that have been collected in earlier batches or time periods, as well as their respective values for the measured quality attributes of the product.

Further partial process models can be described by means of data-based models such as a neural network, a combination of neural networks, or multi-variant models such as the partial least square regression (PLS) method.

It is usually preferred for the production model to comprise a combination of data-based and mechanistic modelling in a hybrid model. Such hybrid models are more robust, since they enable a certain degree of extrapolation which is not the case with pure data-based models. Extrapolation means that they are able to prepare a trustworthy prediction outside the convex envelope of the data set on which they have been trained.

It will be obvious to the person skilled in the art that the preparation of the production model comprises the selection of the best-fitting partial process model for describing the production process and/or the partial processes. Reference is made to the prior art for the provision of models. For example, a process model for a bioreaction was provided with the aid of the method of Hebing et al (U.S. Pat. No. 10,296,708).

Process experts, procurers and literature can typically supply input data. These data are usually collected in a database and used for model training. These data are typically provided to the database in tabular form via a graphic user interface using Microsoft Excel (MS Excel 2010®). It comprises, for example, device unit, area, working force, consumable materials unit and disposal effort. In addition, the necessary quantities for, for example, employees, devices and required areas for the partial processes are listed. Values, value ranges or the value profile for the defined influencing parameter are made available; these represent the process settings. This information is typically collected on a tab for each process or partial process that is to be investigated.

With the aid of a production model, at least one simulation result is calculated according to the above-named definition in accordance with the process settings. Typically, a plurality of simulation results are calculated, in particular those from the above-named list, without being restricted to that. Particularly preferably, the state of the plant modules and/or their plant components, space-time yield and/or process flows are calculated.

For the provision of the attribute functions, fixed influencing parameters, variable influencing parameters and the above-named described parameters of the attribute functions are typically necessary. FIG. 2 shows the different influencing parameters in the case of costs being used as the production quality attribute. The values for the variable influencing parameters are typically calculated with the aid of the production model.

With the aid of the attribute functions, values for the quality attribute for the production process are calculated dynamically for various scenarios on the basis of the calculated simulation results and/or values for the process settings (which together constitute the influencing parameters of the attribute functions).

The influencing parameters of the attribute functions can be divided into various groups. One attribute function is typically developed for each group.

The attribute functions can, for example, be implemented in Matlab (Matlab R2018b).

In one particular embodiment of the method, production costs are predicted as the production quality attribute; in this case, the attribute functions are called cost functions.

If costs are predicted as the production quality attribute, examples of such groups are
investment costs
labor costs
maintenance costs
operating costs
costs of medium and consumable materials (e.g. gases, chemicals, waste, water, electricity . . . )

The use of cost functions has the advantage that a limited number of groups can be defined even for a complex process. The provision of the attribute functions is simplified through the grouping of the influencing parameters.

A biotechnical method has been chosen to illustrate the solution according to the invention. It will be obvious to the person skilled in the art that the described solution can be transferred to other production processes.

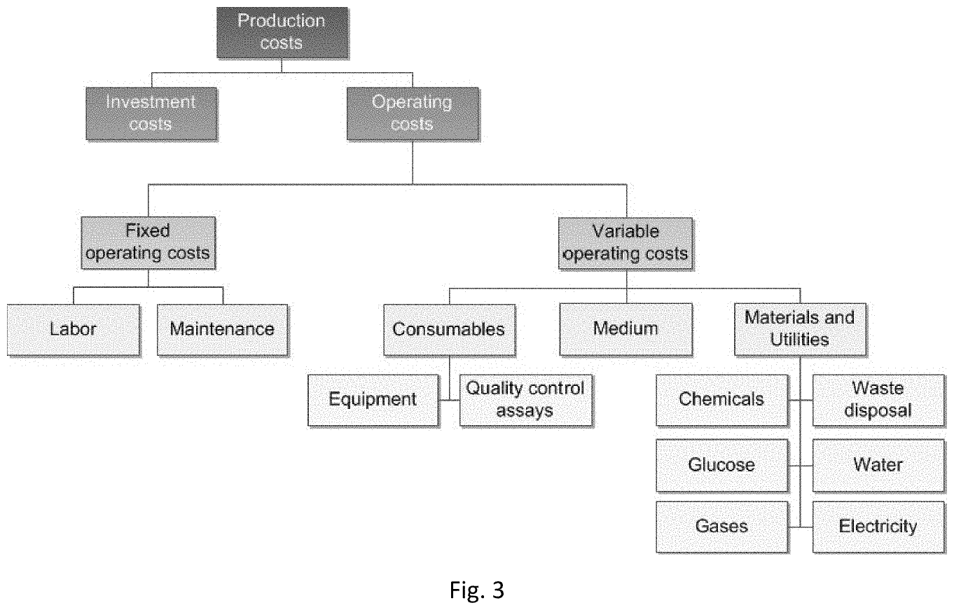

FIG. 3 shows a schematic illustration of the influencing parameters of the attribute functions and their division into fixed and variable influencing parameters.

The production costs can be divided into various groups.

Through the use of appropriate cost functions, the costs can be calculated with reference to the information in the database and the relevant process data of the simulated process.

A cost function is developed for each group. The cost functions are implemented in Matlab (Matlab R2018b). With the aid of the cost functions, the costs for different scenarios (duration, cell density, perfusion rate and so forth) can be calculated dynamically on the basis of the simulated process data.

The input values of the cost functions either originate from the database or from the simulated process data. The cost functions for all the groups are represented below.

### INVESTMENT COSTS

It is preferable to determine the investment costs of a new installation, in order to estimate the profit from future production. An approximate method for calculating the capital costs was implemented in the cost function.

The Lang factor method can be used for the preliminary design [J. L. Novais, N. J. Titchener-Hooker and M. Hoare, “Economic comparison between conventional and disposables-based technology for the production of biopharmaceuticals,” Biotechnology and Bioengineering, vol. 75, no. 2, pp. 143-153, 2001.; G. Towler and R. Sinnott, “Capital Cost Estimating,” in Chemical Engineering Design, Elsevier, 2013, pp. 389-429.]. The direct capital costs can be calculated with equation (1).

$$D F C = c \cdot ( ( {\sum }_{i = 1}^{9} {l}_{i} ) \cdot E P C + E P C + B C ) \qquad ( 1 )$$

where DFC=direct fixed capital [€], c=contingency factor [−], li=Lang factor of cost item i [−], EPC=equipment purchase cost [€], BC=building cost [€]

The purchased device costs (EPC) are multiplied by the sum of the Lang factors lᵢ. Lang factors are multipliers for calculating the EPC in costs for the pipeline construction and so forth. J N Novais et al. publish examples for such Lang factors in a bioprocess, in that a bioprocess was investigated on the basis of single-use devices. A contingency factor c is also described [J. L. Novais, N. J. Titchener-Hooker and M. Hoare, “Economic comparison between conventional and disposables-based technology for the production of biopharmaceuticals,” Biotechnology and Bioengineering, vol. 75, no. 2, pp. 143-153, 2001].

The procurement costs for the equipment typically comprise all the costs for reusable production equipment, for example fermenter housings, bag holders, filter housings. Basic laboratory devices are available in this calculation, and do not have to be purchased. A list of the basic laboratory devices is preferably created for the definition of the production process and the production plant required for it in preparation for providing the production model.

For a more accurate estimate of the building costs (BC), the calculation proposed by D. Petrides can be used [D. Petrides, “BioProcess Design and Economics,” in Bioseparations Science and Engineering, Roger G. Harrison, 2015.]. The building costs can then be calculated, in that the areas of different space classes (A) are multiplied by a specific cost factor (TIC) (see equation (2)).

$$B C = {\sum }_{S} ( {\sum }_{j} {A}_{S , j} \cdot T I {C}_{j} ) \qquad ( 2 )$$

where BC: building cost [€], A_{s,j}: area of process step S and area class j [m²]. TICj: total installed costs [€/m²]

Depending on the facilities required for the process (equipment, quantity of stored medium and so forth), the space required can be ascertained for each modality. The area for each process step (S) can either be assumed or calculated through the addition of individual items of equipment. In a biotechnological process, the method steps of media preparation, reactor preparation, preliminary culture, main culture and harvesting/shutdown are preferably taken into consideration.

The direct cost of plant investment is typically written off over the years of the period of use of the plant. It is therefore converted into an annual capital fee that must be paid during the period of use of the plant. This is done by means of an annual capital charge ratio (ACCR). The investment costs in a year are calculated in that the ACCR is multiplied by the direct plant investment (see equation (3)).

IC=ACCR·DFC (3)

where IC: investment cost [€], ACCR: annual capital charge ratio [−], DFC: direct fixed capital [€]

If a period of use of 10 years and an interest rate of 0.15% are assumed, then an ACCR of 0.199 is assumed, in accordance with G. Towler et al. [G. Towler and R. Sinnott, “Economic Evaluation of Projects,” in Chemical Engineering Design, Elsevier, 2013, pp. 307-354.].

### OPERATING COSTS

The operating costs are preferably described in an attribute function. The fixed operating costs preferably consist of operating costs and maintenance and labor costs. The variable operating costs can be divided into the following groups: consumable materials, media, materials and operating materials. The groups are explained in more detail, and the method of their calculation sketched out below.

### MAINTENANCE

The functionality of a production plant should be retained during its period of use. Parts and devices are therefore repaired and replaced. The costs that arise (maintenance costs) are usually estimated as a fraction (p) of the investment costs, and lie between 3% and 5% [G. Towler and R. Sinnott, “Estimating Revenues and Production Costs,” in Chemical Engineering Design, Elsevier, 2013, pp. 355-387.]. The maintenance costs (MAC) can be calculated with the aid of equation (4). The proportion (p) of 5% was assumed, for example, for all modalities.

MAC=p·IC (4)

where MAC: maintenance cost [€], p: maintenance cost fraction [−], IC: investment cost [€]

### LABOR

The labor costs are preferably defined as fixed operating costs, since they are independent of the product production [D. Petrides, “BioProcess Design and Economics,” in Bioseparations Science and Engineering, Roger G. Harrison, 2015.]. The labor costs preferably take into consideration all the expenses (salary and benefits) for employees who work in connection with the cell culture process. In order to calculate the costs of the personnel required for the various process modalities, a work scheduling exercise is typically carried out for the processes. Employees of various groups, in terms of their functions—operators, process engineers and so forth—are usually involved in a production process. The number (a) of full-time equivalent workers (FTE) required from a specific group (g) can be ascertained for each process step (S) [I. Knappen, M. Temming and J. Krasenbrink, Interviewees, Process Experts. [Interview]. February-July 2019]. The costs for one full-time equivalent worker (FTE) for each group and day (C_{g}) can also be ascertained on the basis of the work of L. Holtmann [L. Holtmann, “Cost evaluation of monoclonal antibody production processes in different operation modes,” Technische Universitat Dortmund, 2014.].

The labor costs for the process steps can be calculated in that the costs of all required full-time workers per day are multiplied by the duration of the process step. The calculation of the labor costs is described in equation (5).

$$L C = {\sum }_{S} {t}_{S} ( {\sum }_{g} {a}_{g} \cdot {C}_{g} ) \qquad ( 5 )$$

where LC: labor cost [€], tS: duration of process step S [d], ag: necessary amount of FTE per employee group [−], Cg: cost per FTE of group g per day [€/d ]

### CONSUMABLE MATERIALS

Single use articles, i.e. consumable materials, preferably comprise all the single-use articles such as filters, bags and quality control samples. In preparation for the provision of the production model and of the attribute functions, all the consumable materials required for the process (quantity and, for example, price or further attribute function parameters) are listed in a database. The consumption costs per batch can be composed of a fixed and variable part. The fixed part takes the fixed costs for consumable material, such as the reactor bag, for one batch into consideration. The variable part takes the costs for consumable materials that vary depending on the operating parameters such as the duration of the main culture, the perfusion rate and the membrane change frequency (using ATF in the perfusion modality) into consideration. These consumable materials include, for example, quality control samples, medial bags and ATF membranes. The costs for consumable materials can be calculated with equation (6).

$$C C = {\sum }_{S} ( {\sum }_{j} {a}_{S , j} \cdot {C}_{j} + {\sum }_{i} ( {\sum }_{j} {v}_{S , i , j} \cdot {C}_{j} ) ) \qquad ( 6 )$$

where CC: consumable cost [€], a_{s,j}: fixed amount of consumable unit j in process step S [−], Cⱼ: cost of consumable unit j [€], v_{s,i,j}: variable amount of i of consumable unit j in process step S [−]

Basic single-use laboratory devices such as Eppendorf tubes, Falcon tubes etc. are not normally taken into consideration.

### MEDIUM

Cells require substrate and other components in order to produce biomass and product. The substrate and other components are provided by the medium. A distinction is usually made between basic medium and feed medium. The basal medium is used in the preliminary culture and as the starting volume in the production bioreactor. Feed medium is added to the production bioreactor continuously during the main culture. The corresponding cost function therefore preferably comprises a fixed and a variable component. The cost function for medium costs for a biotechnological production process is given, for example, in equation (7). A specific conveying medium flow (fFM) is added. In the perfusion process, this medium flow depends on the perfusion rate. It should be emphasized that the feed medium differs for batch and perfusion cultures. For cost calculation, the precise medium flows f_{Fm} are typically calculated and referred to with the aid of the production model (simulation result).

$$M C = {C}_{B M} \cdot {a}_{B M} + {C}_{F M} \cdot {\int }_{{t}_{0}}^{t} {f}_{F M} d t \qquad ( 7 )$$

where MC: medium cost [€], a_{BM}: fixed amount of basal medium from preculture and initial start volume [L], CBM: cost of basal medium [€/L], C_{FM}: cost of feed medium [€/L], f_{FM}: flow of feed medium [L/h], t: duration of main culture [h]

### MATERIALS AND AUXILIARY AGENTS

Materials such as glucose, acids, bases and anti-foaming agent, as well as operating material such as gases, waste disposal, water and electricity should be taken into consideration in the cost calculation of biotechnological processes. Each of the subsidiary groups is explained in more detail below, and the specific cost function presented. The material and auxiliary costs (MUC) are the total of all the cost functions of the subgroups (according to equation (8)).

MUC=Cₘₐₜₑᵣᵢₐₗₛ+C_{gas}+C_{waste disposal}+C_{water}+C_{electricity} (8)

where MUC: materials and utilities cost [€], Cₘₐₜₑᵣᵢₐₗₛ: materials cost [€], C_{gas}: gas cost [€], C_{waste disposal}: waste disposal cost [€], C_{water}: water cost [€], C_{electricity}: electricity cost [€]

### MATERIALS

Glucose is usually required as a growth substrate in biological processes [N. P. Shirsat, N. J. English, B. Glennon and M. Al-Rubeai, “Modelling of Mammalian Cell Cultures,” in Animal Cell Culture, Springer International Publishing, 2015, pp. 259-325.]. The concentration of glucose in the feed medium is usually not enough, and additional glucose is therefore added. Bases and acids are needed in order to maintain the desired pH value in the bioreactor. Foam develops as a result of gassing in the bioreactor. Anti-foaming agent is used to prevent excessive foaming The materials costs for the duration of the main culture accordingly are found from equation (9).

$${C}_{m a t e r i a l s} = {\sum }_{j} {C}_{j} \cdot {\int }_{{t}_{0}}^{t} {f}_{j} d t \qquad ( 9 )$$

where Cₘₐₜₑᵣᵢₐₗₛ: material cost [€], Cⱼ: specific cost of chemical j [€/L ], fⱼ: flow of material [L/h], t: duration of main culture [h]

The individual process flows fⱼ for the cost calculation are ascertained with the aid of the production model. From the process settings it is possible, for example, to specify how much of the reactor volume is replaced by new medium each day. The time-series of the individual flows are then calculated using the process model. There is, for example, a purge current that is needed to maintain a constant cell density. This is calculated with reference to the production model.

### GASES

Gases supply important nutrients. Oxygen, nitrogen and air are usually introduced into the bioreactor with a suitable gas supply strategy. N2 is usually only used in the starting phase of the bioreactor in order, for example, to calibrate sensors. Consumption is small, and is therefore not taken into consideration. The consumption of O2 and air are usually calculated with reference to the maximum gas flows (=process settings) that the reactor can handle. It is assumed that the cell culture runs with the maximum gas flows. The gas costs during the main culture can be estimated with equation (10).

$${C}_{g a s} = {\sum }_{j} {f}_{j} \cdot {C}_{j} \cdot t \qquad ( 10 )$$

where C_{gas}: gas cost [€], fⱼ maximum flow of gas j [L/h], t: specific cost of gas j [€/L ]t: duration of main culture [h]

### WASTE DISPOSAL

Waste products arise during a production process. In particular when single-use articles are used, large quantities of solid waste are generated; this partial process gains relevance in this case for the production quality attribute. Contaminated waste is a big problem in bioprocesses. The deactivation of biological residues must therefore be considered. The costs for solid and liquid (contaminated/non-contaminated) wastes can be calculated in that the total quantity (weight/volume) is added and multiplied by a cost factor (see equation (11)). Depending on the type, the waste for one batch can either be fixed or variable.

$${C}_{w a s t e} = {\sum }_{S} ( {\sum }_{j} {a}_{S , j} \cdot {C}_{j} + {\sum }_{i} ( {\sum }_{j} {v}_{S , i , j} \cdot {C}_{j} ) ) \qquad ( 11 )$$

where C_{waste}: waste costs [€], as,j: fixed quantity (weight/volume) of the waste type j (e.g. solid waste, contaminated liquid waste, non-contaminated liquid waste) in method step S [kg, L], Cj: specific costs of the waste type j [€/kg, €/L] vs, i, j: variable quantity (depending on, for instance, duration of the main culture) of i of the waste type j in method step S

### WATER

Preferably only process water is considered in this group. Water for the manufacture of medium, solutions and so forth is typically taken into consideration in the medium and materials groups. Process water is needed for flushing the filter modules (depth filters, sterile filters, ATF module). The required quantity of water can be provided by standard operating procedures (SOPs). The corresponding cost function is given in equation (12).

$${C}_{w a t e r} = {\sum }_{S} ( {\sum }_{j} {a}_{S , f} \cdot C + {\sum }_{i} ( {\sum }_{j} {v}_{S , i , j} \cdot C ) ) \qquad ( 12 )$$

where C_{water}: water cost [€], a_{s,f}: fixed amount of water per utilization unit j (e.g. depth filter, sterile filter) in process step S [L], C: specific cost of water [€/L], v_{s,i,j}: variable i amount of utilization unit j in process step S [L]

### ELECTRICITY

Electricity for heating, ventilating and air-conditioning (HVAC) makes up 65% of the total energy requirement of a pharmaceutical plant [P. Bunnak, R. Allmendinger, S. V. Ramasamy, P. Lettieri and N. J. Titchener-Hooker, “Life-cycle and cost of goods assessment of fed-batch and perfusion-based manufacturing processes for mAbs,” Biotechnology Progress, vol. 32, no. 5, pp. 1324-1335, 2016.]. Further energy-intensive processes include the manufacture of purified water (PW) and infection water (WFI), as well as devices for cleaning and sterilization. Because PW and WFI costs are taken into consideration in the “water” group and no CIP or SIP devices are used in the upstream processes, only the HVAC operating costs are taken into consideration for the electricity costs. With the aid of [B. B. Barak I. Barnoon, “Lifecycle Cost Analysis for Single-Use Systems. Less complicated single-use systems have more favorable lifecycle economics.”, 2008. [Online]. Available: http ://www.biopharminternational.com/lifecycle-cost-analysis-single-use-systems?id=&sk=&date=&pageID=2. [Accessed 3 Jun. 2019].] specific cost values per day and per area class were calculated for the HVAC (heating, ventilating and air-conditioning). With the ascertained areas of the different area classes, the costs were calculated in accordance with equation (13).

$${C}_{electricity} = {\sum }_{S} ( {t}_{s} {\sum }_{j} {A}_{S , j} \cdot {C}_{j} ) \qquad ( 13 )$$

where C_{electricity}: electricity cost [€], tₛ: duration of process step S [d], A_{s,j}: area of process step S and area class j [m²], Cⱼ: costs per area class per day and square meter [€/d/m²]

### SIMULATION OF THE PRODUCTION PROCESS

In the method according to the invention, a batch of the production process is simulated. Values, value ranges or value profiles for the process settings are provided for the simulation. For a biotechnological process, the perfusion rate, maximum cell density, scale of the production bioreactor and duration of the individual steps (medium preparation, reactor preparation, preliminary culture, main culture, harvesting and shutdown) are, for example, provided. With the aid of the process model, in particular the flow rate, particularly preferably the temporal profile of the biomass, of the product and of all the other metabolites, also including all the flows (medium, feed . . . ) are.

During a biotechnological perfusion process, cells are held with the aid of a cell retention system in the bioreactor, and at the same time fresh medium is continuously added while “used” medium is withdrawn. If the cell retention takes place, for example, with an ATF module (alternating tangential flow filtration), the antibody produced by the cells is not retained by the cell retention system, but can pass through the membrane. Over time, the filter membrane becomes clogged by a filter cake (“membrane fouling”), which has the consequence that some of the antibody produced remains in the bioreactor, as a result of which antibody accumulates in the bioreactor. The percentage proportion of antibody that continues to pass through the membrane is referred to as the “sieving coefficient”. The membrane fouling depends on the flow through the membrane (“filter flux” in L/m²/d).

In order to compare the profitability of the different modalities, it is crucial to use reliable process data. This is done through process simulation. Process models that already exist are therefore used. The process models are parameterized through experiments at a scale of 1-L. The initial conditions are scaled up using a linear estimation to represent the 2000-L scale. Using the process model and the scaled-up initial conditions, process data are simulated that describe the process scenarios that have been designed. This simulation method is also an element of the cost calculation model.

An underlying operating mode (basic scenario) can be defined for each process modality. With the aid of the method according to the invention, the basic scenarios can be simulated and evaluated on an economic basis.

The method can further be used as a foundation for optimizing the operating mode of the perfusion process using ATF in respect of economic parameters. For that reason, an optimization function using a genetic optimization algorithm has been developed and solved, and is made available by Matlab (Matlab R2018b).

The ATF filter modules are a high cost factor in the perfusion process using ATF. They must be changed during the process as they become blocked over the course of time. When they are blocked, less mAb is sieved into the harvest by the filter membrane. Both the costs for the filter membranes as well as the quantity of mAb in the harvest affect the specific costs of the goods sold (sCOGS) [1]. By minimizing the sCOGS, the optimum number and time points of the filter membrane replacements can be determined; these represent an optimizable process setting.

The fitness function of the optimization is given in equation (14).

$${min}_{{t}_{1} , … , {t}_{n}} s C O G S ( {t}_{1} , … , {t}_{n} ) \qquad ( 14 )$$

where sCOGS: specific cost of goods sold [€/g], tᵢ: timepoint of membrane change number i [h], n: number of membrane changes [−]

[1]COGS=costs of the goods sold, i.e. direct costs associated with the manufacture of the goods sold by a company. [Investopedia, “Definition Cost of Goods Sold,” [Online]. Available: https://www.investopedia.com/terms/c/cogs.asp. [Accessed 14 Jul. 2019]. ]

In a further embodiment of the method, the space-time yield (=simulation result) is used in order to optimize the productivity of the production process. This can also be used to compare fermentation processes, for example based on fed-batch and on perfusion. The space-time yield directly influences the sCOGS (€/g). The viable cell density and the specific productivity of a cell mainly have an effect on the quantity of mAb produced and thereby on the space-time yield.

In one particular embodiment, the method according to the invention takes the risk factors of the production process into consideration. Contaminations, bag leaks or production downtimes are risk factors that lead to delays in the timetable and to fewer batches per year, and should therefore be taken into consideration.

Success/failure rates for the process have been implemented for this purpose in order to cover these faults. The success rates are typically ascertained by experts from process knowledge. The success rate(s) are typically taken into consideration as parameters of the attribute function.

In a further special embodiment, a scale effect can be taken into consideration. For example, the capital costs per product unit become smaller with increasing scale of the production plant. This is a result of economies of scale [G. Towler and R. Sinnott, “Capital Cost Estimating,” in Chemical Engineering Design, Elsevier, 2013, pp. 389-429]. The capital costs for the larger plant can be calculated on the basis of the capital costs of the smaller plant using equation (15).

$${cost}_{2} = {{cost}_{1} ( \frac{{size}_{2}}{{size}_{1}} )}^{n} \qquad ( 15 )$$

where cost: cost of plant [€], s: size of plant [i.e. kg, L], n: exponent [−]

The process scale is usually specified in the process settings. With the aid of the method, the calculation can also be carried out and compared for different scales, and the scale effect can thereby be investigated.

The results of the cost calculation are, typically, cost reports and parameter and sensitivity studies.

A perfusion process is, for example, optimized with the method according to the invention.

This example is explained in somewhat more detail below without, however, wishing to restrict the invention to this embodiment.

### Example: Optimization of a Perfusion Process:

The aim of a perfusion process is to achieve the highest possible concentration of the antibody in the harvest in order to then purify this in the subsequent downstream process. This in turn means that—depending on the fouling—the filter membrane must be exchanged after a certain time for a new, fresh module, so that the antibody can again pass through the membrane unhindered, whereby the product concentration in the harvest rises again.

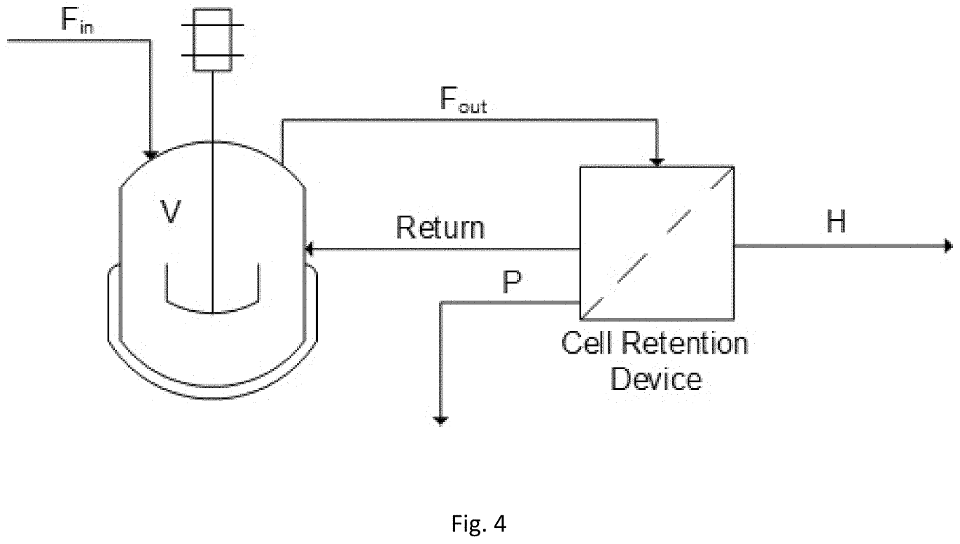

FIG. 4 shows a diagram of a biotechnological perfusion process with retention. Fin and Font respectively represent incoming and outgoing medium flows, depending on the perfusion rate. H represents the harvest, and P the purge current.

Different influencing factors are a particular interest in the development of a biotechnological perfusion process with a cell retention system.

In particular, the optimum time points at which the filter membrane is exchanged so that the highest quantity of antibody is found in the harvest at any given time should be determined. At the same time, however, the membrane should be exchanged as infrequently as possible during the running time, since an ATF filter module makes a significant contribution to the total costs of the process (˜9%). It is also necessary to decide how many membrane replacements can take place, if the process is still commercially viable.

A further question to be answered is the total running time of a perfusion process. It has been observed that the cell viability, and therefore also the specific productivity, falls after a certain cultivation duration. It is therefore appropriate to ascertain when the time point has been reached at which the process is no longer commercially viable—to be more precise, when the specific costs for the antibody (specific cost of goods) reaches a specific threshold value.

A perfusion process can be described with the aid of a cell and process model. The model is based on a combination of a metabolic model with differential equations whose parameters are again calibrated with reference to experimental data. This approach to the model development is already known [U.S. Pat. No. 10,296,708; Hebing, L., Neymann, T., Thine, T., Jockwer, A., and Engell, S. (2016). Efficient generation of models of fed-batch fermentations for process design and control. DYCOPS, 621-626].

On the basis of this approach, the model has been supplemented with the perfusion modes of cell retention with an ATF module and of cell retention with a settler.

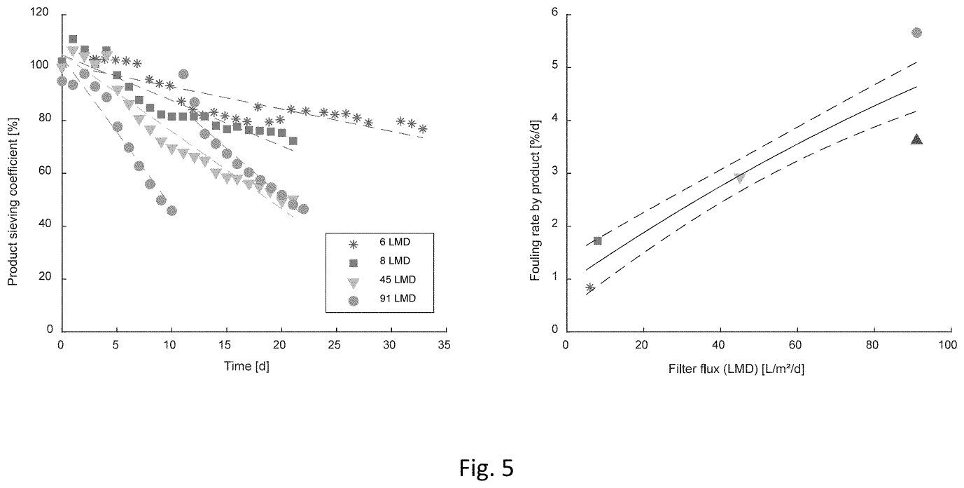

For the extension of the process model, the antibody retention for different membrane flows has been determined experimentally, and the results are illustrated, by way of example, for a product in FIG. 5. These experiments must be carried out again both for each cell line and for each product, since the fouling rate depends heavily on the cell line being used. The product sieving coefficient is calculated for different membrane flow rates according to the following formula. [J. Walther, J. McLarty, T. Johnson (2018) The effects of alternating tangential flow (ATF) residence time, hydrodynamic stress, and filtration flux on high-density perfusion cell culture. Biotechnology and Bioengineering.]

$$σ = \frac{{c}_{h}}{{c}_{r}} \qquad ( 16 )$$

wherein the following definitions apply: σ: product sieving coefficient [%], ch: antibody concentration in the harvest flow (post-ATF) [g/L], cr: antibody concentration in the reactor (pre-ATF) [g/L]

On the basis of the product throughput coefficient, the fouling rate can be calculated with the aid of the following formula:

q_{Fouling rate}=f(LMD) (17)

q_{Fouling rate}=β₀+β₁·β₃·LMD^{2 (}18)

where β₀, β₁, β₃ are the parameters of the quadratic function that have been ascertained with the aid of the data points from FIG. 5b. LMD is the filter flux (flow through the membrane per m2 of membrane area in L/m2/d).

On the left, FIG. 5 shows the product sieving coefficient over the cultivation time for different flow rates. On the right, FIG. 5 shows the fouling rate against different membrane flows (filter flux).

In order now to be able to observe the product retention in the dynamic process model as well, the model is extended with the following equation.

$$\frac{d σ}{d t} = - {q}_{Fouling rate} \qquad ( 19 )$$

Cost evaluation of different biotechnological process modalities.

The process model was extended by a further functionality for the dynamic calculation of the manufacturing costs (Cost of Goods Sold, COGS). In this calculation method, process data are generated with the aid of the dynamic process model, and these, together with data from a specific database, are then converted by way of cost functions into manufacturing costs.

Using the method developed, it is possible to evaluate which process parameters have the greatest effect on the manufacturing costs and thus offer the most effective lever for process development. Using optimization functions, it is then also possible to determine in what way the manufacturing costs can be lowered, or the productivity of the process can be maximized.

The dynamic process model, extended by the commercial evaluation of different process modalities, offers the possibility of performing an optimization in respect of the operating costs. An optimization function is defined for this purpose, and solved with the aid of an optimization algorithm (genetic algorithm) integrated into Matlab (Matlab R2018b).

The number of membrane replacements is, for example, a large cost factor in perfusion processes using an ATF module. The ATF filter membrane must be replaced during the process, since this becomes clogged over time, and thus hinders the flow of the antibody into the harvest. At the same time, the ATF filter membranes contribute heavily to the total manufacturing costs, and the number of filter replacements should therefore be kept to a low level.

By minimizing the manufacturing costs, both the optimum number of membrane replacements and the time points for the replacements can be calculated. In this case, the optimization problem can be defined as follows:

$${min}_{{t}_{1} , … , {t}_{n}} s C O G S ( {t}_{1} , … , {t}_{n} ) \qquad ( 20 )$$

sCOGS: specific cost of goods sold [€/g]: number of membrane replacements [−], ti: time point of membrane replacement i [h].

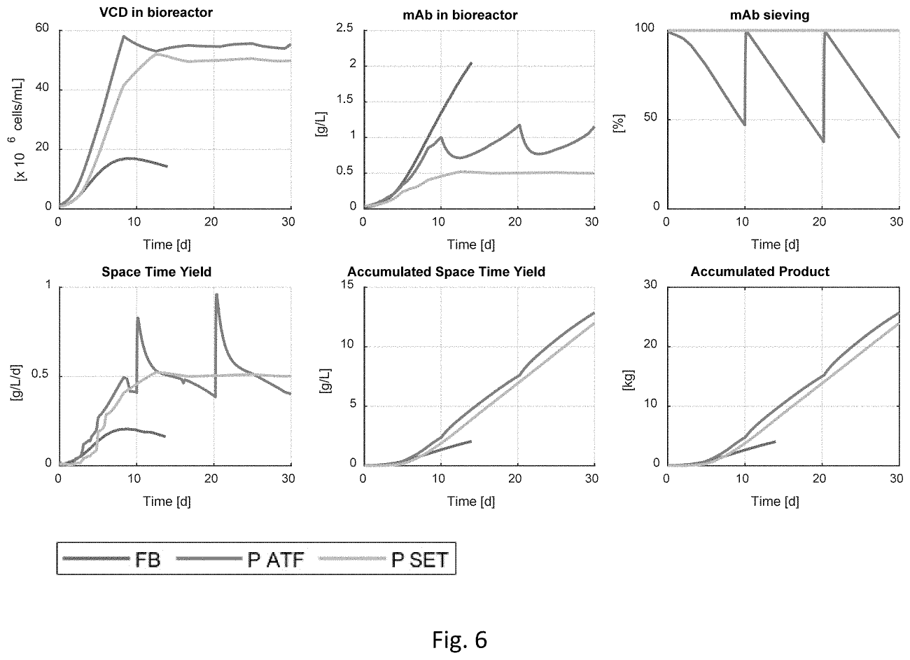

An optimization of this sort is carried out with the aid of an exemplary data set, the results of which can be seen in FIG. 6 (c): With three membrane replacements at time points t1=9.8 d, t2=16.7 d and t3=24.6 d the specific manufacturing costs can be lowered by 1%, and the quantity of antibody produced raised by 5%, as shown in the figure.

The method is conceived in such a way that both the model and the associated cost functions can be extended by any other desired parameters. For example, the model has been extended by a function that describes the probability of process downtime depending on the cultivation duration, influenced by risk factors such as contaminations or the period of use of the single-use equipment. The total process runtime can be optimized with the aid of this function, and the risk to the process minimized.

A further possible application for a process optimization might be the calculation of the optimum cultivation duration of the cells, since the viability, and consequently the productivity, falls over time, and the profitability of the process falls with increasing cultivation duration.

FIG. 6 shows process data optimized with the aid of the solution according to the invention in respect of the operating costs through the calculation of the optimum time points of the ATF filter membrane replacement. Curve (a) shows the profile of the viable cell density (VCD) in the bioreactor. Curve (b) shows the profile of the concentration of antibody (mAb) in the bioreactor. Curve (c) shows the profile of the antibody retention coefficient with the three above-named membrane replacements for t=10 d and 20 d. Curve (d) shows the space-time yield. Curve (e) shows the accumulated space-time yield, and curve (f) shows the accumulated product. All the curves are calculated for a fed-batch process (FB, blue), for a perfusion process with ATF model (red), and for a perfusion process with a settler (yellow) respectively.

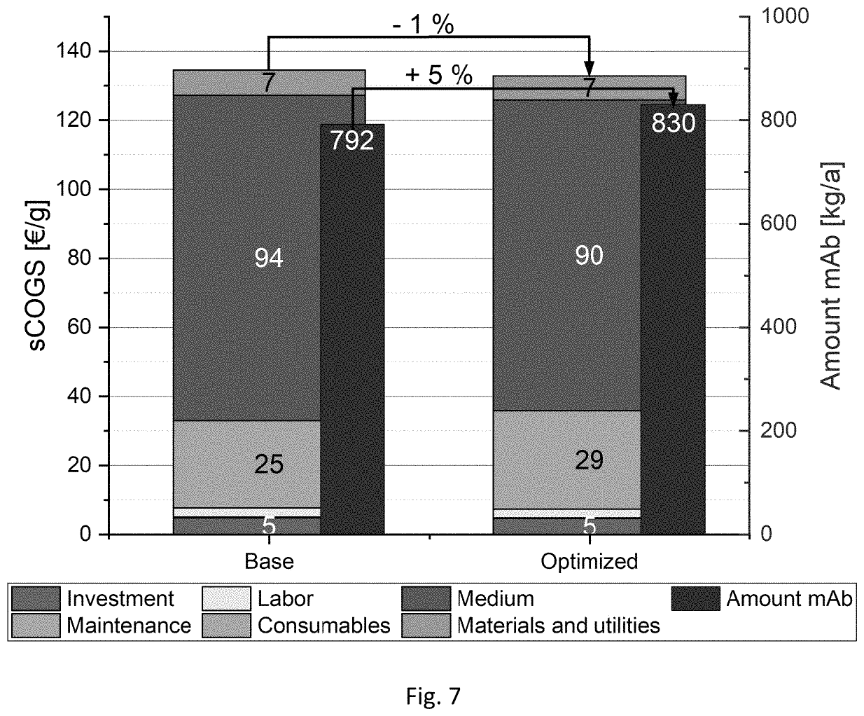

FIG. 7 shows the specific manufacturing costs and the quantity of antibody produced for a perfusion process with an ATF module in comparison, with, on the left, the current process with two membrane replacements at t1=10 d and t2=20 d, and on the right, the optimized process with three membrane replacements.

The method presented has been described for basic scenarios for fed-batch perfusion with alternating tangential flow filtration and inclined settler. The comparison of the basic scenarios shows that perfusion modalities can cover the need for high production quantities, but do have a higher sCOGS in comparison with the FB strategy. Sensitivity studies yielded cell-related parameters, perfusion rates and medium costs as the main cost-drivers for perfusion modalities. Parameter studies showed that it is even possible to undercut the sCOGS of the FB basic scenario. In addition, they show that the increase in the space-time yield, and the reduction in the perfusion rate, have the biggest influence on the cost savings. Bearing in mind the fact that the space-time yield is directly influenced by the viable cell density and the cell-specific productivity, the cell-specific productivity has a greater influence on the sCOGS than the viable cell density. This can be achieved on the one hand in that attention is paid early to the selection of highly productive clones, and on the other hand that the performance of the bioreactor is optimized in order to increase the oxygen transfer and thereby the viable cell density. Assuming that the space-time yield is not affected by the reduction in the perfusion rate, a perfusion rate of 0.5 L/L/d will only be sufficient using the settler modality to undercut the sCOGS of the FB basic scenario.

What is claimed is:

1. A computer-implemented method for designing a production process including multiple partial processes carried out in a production plant comprising at least one plant component with a limited period of use, wherein the production process comprises at least one replacement or cleaning step of the plant components with limited period of use, and is characterized by influencing parameters as process settings and their values, value ranges, or time-series data for a prediction instance, process simulation results and a target value for a production quality attribute, wherein the method comprises the following steps:
a. provisioning a production model wherein the production model specifies or represents mathematical relationships between process simulation results and the process settings;
b. provisioning attribute functions, wherein an attribute function specifies or represents mathematical relationships between the process settings and/or the process simulation results as input to the attribute functions, and the production quality attribute as the output of the attribute functions;
c. receiving values or a value range for the process settings for a prediction instance in the form of time-series data, wherein the periods of use for the respective plant components with limited period of use are defined in the process settings;
d. receiving parameters for the attribute functions;
e. calculating the process simulation results by the production module from a.;
f. calculating a value for the production quality attribute by solving the attribute functions from b., wherein the values or value ranges for the process settings from c. and/or the process simulation results from e. and the parameters for the attribute functions from d. are used for the solution of the attribute functions;
g. varying at least one period of use for the respective plant components with limited period of use, and repetition of the steps e. to f.;
h. repeating the steps f. to g. until the value of the production quality attribute reaches an optimum;
i. outputting an optimum configuration of the production process in that at least the period of use of the respective plant components with limited period of use is optimized.

2. The method as claimed in claim 1, wherein the production model is a hybrid model that comprises a plurality of empirical and/or mechanistic process models or partial process models.

3. The method as claimed in claim 1, further comprising calculating: optima for the production quality attribute, optima for the period of use for the respective plant components with limited period of use, and further process settings through systematic variation of the process settings, and wherein the optima are output and/or the optima are used for the process settings for control of the production process.

4. The method as claimed in claim 3, wherein the influence of the process settings on the value of the production quality attribute is quantified and output.

5. The method as claimed in claim 1, wherein the parameters for the attribute functions comprise success rates and/or risk factors for the production process.

6. The method as claimed in claim 1, wherein the process settings comprise scales of the production process and/or partial processes.

7. The method as claimed in claim 1, wherein the production quality attribute is the associated costs.

8. The method as claimed in claim 1, wherein alternatives for partial processes are represented in the production process, production quality attributes for alternatives are calculated, and these are output for comparison.

9. The method as claimed in claim 1, wherein, in step c., process settings are measured and received online.

10. The method as claimed in claim 3, wherein the production quality attribute and/or the optima for the process settings are used for the output of warnings based on a predefined tolerance range.

11. The method as claimed in claim 1, wherein the production process is a biotechnological process.

12. The method as claimed in claim 11, wherein the biotechnological process is a perfusion process that comprises an alternating tangential flow filtration module or settler as the retention system.

13. A system configured for designing a production process including multiple partial processes carried out in a production plant comprising at least one plant component with a limited period of use, wherein the production process comprises at least one replacement or cleaning step of the plant components with limited period of use, and is characterized by influencing parameters as process settings and their values, value ranges, or time-series data for a prediction instance, process simulation results and a target value for a production quality attribute, the system comprising:
a module configured to:
define the production process and the partial processes; and
select the production quality attribute for the prediction;
a model module comprising at least one production model of the production process and attribute functions, wherein the model module is configured to:
receive values or value ranges for the process settings, and parameters for the attribute functions; and
calculate a production quality attribute with the aid of the production model and the attribute functions;
an optimization module configured to calculate optima for the production quality attribute and the process settings;
a module configured to output the calculated production quality attribute and optima for the process settings.

14. The system as claimed in claim 13, wherein the optimization module is configured to quantify the influence of the process settings on the value of the production quality attribute.

15. A non-transitory computer-readable medium with instructions which, in reaction to execution of the instructions by a computer system, cause the computer system to carry out the following steps
a. provisioning a production model wherein the production model specifies or represents mathematical relationships between process simulation results and the process settings;
b. provisioning attribute functions, wherein an attribute function specifies or represents mathematical relationships between the process settings and/or the process simulation results as input to the attribute functions, and the production quality attribute as the output of the attribute functions;
c. receiving values or a value range for the process settings for a prediction instance in the form of time-series data, wherein the periods of use for the respective plant components with limited period of use are defined in the process settings;
d. receiving parameters for the attribute functions;
e. calculating the process simulation results by the production module from a.;
f. calculating a value for the production quality attribute by solving the attribute functions from b., wherein the values or value ranges for the process settings from c. and/or the process simulation results from e. and the parameters for the attribute functions from d. are used for the solution of the attribute functions;
g. varying at least one period of use for the respective plant components with limited period of use, and repetition of the steps e. to f.;
h. repeating the steps f. to g. until the value of the production quality attribute reaches an optimum;
i. outputting an optimum configuration of the production process in that at least the period of use of the respective plant components with limited period of use is optimized.

16. The method as claimed in claim 1, further comprising outputting the production quality attribute from f. as a single quality value or as a curve against time.
